(19) United States
(12) Patent Application Publication
(10) Pub. No.: US 2009/0284287 A1
(43) Pub. Date: Nov. 19, 2009

(54) Output buffer circuit and integrated circuit

(75) Inventor: Manabu Kosuge, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/385,800

(22) Filed: Apr. 21, 2009

(30) Foreign Application Priority Data
May 19, 2008 (JP) 2008-131250

(51) Int. Cl. H03K 3/00

(52) U.S. Cl. 327/109; 327/108

(57) ABSTRACT

Disclosed herein is an output buffer circuit including: a power supply; an output circuit having a first field-effect transistor and a second field-effect transistor; an output control circuit; a substrate-voltage control circuit; a gate-voltage control circuit; and a signal supplying section.

### BACKGROUND OF THE INVENTION

1. Field of the Invention

The present invention relates to an output buffer circuit applied to an output section of an LSI (Large Scale Integrated) circuit connected to another LSI and also relates to an integrated circuit including the output buffer circuit.

2. Description of the Related Art

If a plurality of semiconductor chips (or LSIs) is mounted on the same package, there are some cases in which the output sections each employed in one of the chips are connected to each other. In such cases, if the power supplies for core and interface sections employed in a particular one of the semiconductor chips are turned off, a current may undesirably flow from another one of the chips to the particular chip having the power supplies turned off.

In order to solve this problem, there has been proposed a variety of technologies as disclosed in documents such as Japanese Patent Laid-Open Nos. 2003-289103 (hereinafter referred to as Patent Document 1) and 2002-100735 (hereinafter referred to as Patent Document 2).

If a plurality of chips (or LSIS) is connected in parallel by directly wiring the outputs of the LSIs to each other and it is desired to put a specific one of the chips in a turned-off state, a signal may inevitably propagate from a chip to be put in a turned-on state to the specific chip to be put in a turned-off state. In order to solve this problem, Patent Document 1 discloses a technology for sustaining the power supply of the interface section employed in the specific chip to be put in a turned-off state in a turned-on state as it is while turning off the power supply of the core section to be put in a turned-off state employed in the specific chip in order to put the core section in a Hi-Z (high impedance) state as an absolutely required condition.

By the way, in order to put the power supply of a circuit serving as the interface section employed in a chip in a turned-off state, typically, a control circuit is inserted between chips.

In accordance with a technology disclosed in Patent Document 2, in order to put the power supply of a circuit serving as the interface section employed in a chip in a turned-off state, a dedicated control signal is used to serve as a signal for executing control to put the power supply of a circuit serving as the interface section employed in a chip in a turned-off state.

### SUMMARY OF THE INVENTION

However, the solutions described above raise the following problems. First of all, the number of components increases and the power consumption cannot be reduced because the power supply of a circuit serving as the interface section cannot be put in a turned-off state. In addition, at a power-off time, control such as control executed only by the core section is required. As a result, the LSI chip system also referred to hereafter as an integrated circuit system unavoidably becomes complicated.

In order to solve the problems described above, the embodiments of the present invention provide an output buffer circuit capable of preventing the number of components from increasing, reducing the power consumption and preventing the LSI chip system including integrated circuits from becoming complicated and provides an integrated circuit including the output buffer circuit.

In order to solve the problems described above, in accordance with a first embodiment of the present invention, there is provided an output buffer circuit employing: a power supply; an output circuit having a first field-effect transistor and a second field-effect transistor which are connected in series between reference electric potentials by linking the drain electrode of the first field-effect transistor to the drain electrode of the second field-effect transistor through a connection point serving as an output node; an output control circuit for controlling an operation to put the output of the output circuit in the state of a first level, the state of a second level or a high-impedance state; a substrate-voltage control circuit for connecting the substrate of the first field-effect transistor employed in the output circuit to the power supply of the output circuit when the power supply is put in a turned-on state; a gate-voltage control circuit for supplying a signal received from another integrated circuit connected to the output node of the output circuit to the gate electrode of the first field-effect transistor employed in the output circuit when the power supply of the output buffer circuit has been put in a turned-off state and the signal received from the other integrated circuit has been in the state of the first level; and a signal supplying section configured to supply a signal received from another integrated circuit connected to the output node of the output circuit to the substrate of the first field-effect transistor employed in the output circuit when the power supply of the output buffer circuit has been put in a turned-off state and the signal received from the other integrated circuit has been put in the state of the first level.

It is desirable to provide a configuration in which the signal supplying section is implemented as a PN diode created between the drain area and substrate of the first field-effect transistor employed in the output circuit to serve as a diode for supplying a signal received from the other integrated circuit as a signal set in the state of the first level to the substrate.

It is desirable to provide a configuration in which, when the power supply of the output circuit has been put in a turned-off state, the signal supplying section selectively connects the substrate of the first field-effect transistor employed in the output circuit to the output node of the output circuit in order to supply a signal received from the other integrated circuit connected to the output node as a signal set in the state of the first level to the substrate of the first field-effect transistor.

It is desirable to provide a configuration in which: the substrate-voltage control circuit employs: a first switch connected between the power supply and the substrate of the first field-effect transistor employed in the output circuit; and a first control section configured to control an operation to put the first switch in a turned-on state when the power supply is put in a turned-on state and an operation to put the first switch in a turned-off state when the power supply is put in a turned-off state, whereas the gate-voltage control circuit employs: a second switch connected between a first gate control line for controlling an electric potential appearing on the gate electrode of the first field-effect transistor employed in the output circuit and a second gate control line wired to the gate electrode of the first field-effect transistor; a third switch connected between the output node of the output circuit and the second gate control line wired to the gate electrode of the first field-effect transistor employed in the output circuit; and a second control section configured to control an operation to put the second switch in a turned-on state and put the third switch in a turned-off state when the power supply is put in a turned-on state and an operation to put the second switch in a turned-off state and put the third switch in a turned-on state when the power supply is put in a turned-off state.

It is desirable to provide a configuration in which: the first switch employed in the substrate-voltage control circuit is created as a third field-effect transistor which is put in a turned-off state by a signal set at the first level and put in a turned-on state by the signal set at the second level; when the power supply is put in a turned-on state, the first control section employed in the substrate-voltage control circuit sustains an electric potential appearing on the gate electrode of the third field-effect transistor at the second level but, when the power supply is put in a turned-off state, on the other hand, the first control section connects the gate electrode of the third field-effect transistor to a connection node wired to the output node of the output circuit to serve as a connection node for connecting the output buffer circuit to another integrated circuit so as to sustain the electric potential appearing on the gate electrode of the third field-effect transistor at an electric potential appearing on the connection node; the second switch employed in the gate-voltage control circuit is created as a fourth field-effect transistor which is put in a turned-off state by a signal set at the first level and put in a turned-on state by the signal set at the second level; the third switch employed in the gate-voltage control circuit is created as a fifth field-effect transistor which is put in a turned-off state by a signal set at the first level and put in a turned-on state by the signal set at the second level; and when the power supply is put in a turned-on state, the second control section employed in the gate-voltage control circuit sustains an electric potential appearing on the gate electrode of the fourth field-effect transistor at the second level but, when the power supply is put in a turned-off state, on the other hand, the second control section connects the gate electrode of the fourth field-effect transistor to the connection node wired to the output node of the output circuit to serve as a connection node for connecting the output circuit to another integrated circuit so as to sustain the electric potential appearing on the gate electrode of the fourth field-effect transistor at an electric potential appearing on the connection node.

It is desirable to provide a configuration in which: the substrate-voltage control circuit employs: a first switch connected between the power supply and the substrate of the first field-effect transistor employed in the output circuit; and a first control section configured to control an operation to put the first switch in a turned-on state when the power supply is put in a turned-on state and an operation to put the first switch in a turned-off state when the power supply is put in a turned-off state, the gate-voltage control circuit employs: a second switch connected between the a first gate control line for controlling an electric potential appearing on the gate electrode of the first field-effect transistor employed in the output circuit and a second gate control line wired to the gate electrode of the first field-effect transistor; a third switch connected between the output node of the output circuit and the second gate control line wired to the gate electrode of the first field-effect transistor employed in the output circuit; and a second control section configured to control an operation to put the second switch in a turned-on state and put the third switch in a turned-off state when the power supply is put in a turned-on state and an operation to put the second switch in a turned-off state and put the third switch in a turned-on state when the power supply is put in a turned-off state, the signal supplying section includes a fourth switch provided between a connection node wired to the output node of the output circuit to serve as a connection node for connecting the output circuit to another integrated circuit and the substrate of the first field-effect transistor, and the first control section controls an operation to put the fourth switch in a turned-on state when the power supply is put in a turned-off state.

It is desirable to provide a configuration in which: the first switch employed in the substrate-voltage control circuit is created as a third field-effect transistor which is put in a turned-off state by a signal set at the first level and put in a turned-on state by the signal set at the second level; when the power supply is put in a turned-on state, the first control section employed in the substrate-voltage control circuit sustains an electric potential appearing on the gate electrode of the third field-effect transistor at the second level but, when the power supply is put in a turned-off state, on the other hand, the first control section connects the gate electrode of the third field-effect transistor to a connection node wired to the output node of the output circuit to serve as a connection node for connecting the output circuit to another integrated circuit so as to sustain the electric potential appearing on the gate electrode of the third field-effect transistor at an electric potential appearing on the connection node; the second switch employed in the gate-voltage control circuit is created as a fourth field-effect transistor which is put in a turned-off state by a signal set at the first level and put in a turned-on state by the signal set at the second level; the third switch employed in the gate-voltage control circuit is created as a fifth field-effect transistor which is put in a turned-off state by a signal set at the first level and put in a turned-on state by the signal set at the second level; when the power supply is put in a turned-on state, the second control section employed in the gate-voltage control circuit sustains an electric potential appearing on the gate electrode of the fourth field-effect transistor at the second level but, when the power supply is put in a turned-off state, on the other hand, the second control section connects the gate electrode of the fourth field-effect transistor to the connection node wired to the output node of the output circuit to serve as a connection node for connecting the output circuit to another integrated circuit so as to sustain the electric potential appearing on the gate electrode of the fourth field-effect transistor at an electric potential appearing on the connection node; the fourth switch employed in the signal supplying section is created as a sixth field-effect transistor which is put in a turned-off state by a signal set at the first level and put in a turned-on state by the signal set at the second level; and the gate electrode of the sixth field-effect transistor is connected to the power supply to serve as a sub-power supply for generating a voltage corresponding to the first level for putting the sixth field-effect transistor in a turned-off state when the power supply is put in a turned-on state and generating a voltage corresponding to the second level for putting the sixth field-effect transistor in a turned-on state when the power supply is put in a turned-off state.

It is desirable to provide a configuration in which, when the power supply is put in a turned-off state, the second control section sustains an electric potential appearing on the gate electrode of the second field-effect transistor employed in the output circuit at an electric potential that puts the second field-effect transistor in a turned-off state.

In accordance with a second embodiment of the present invention, there is provided an integrated circuit including an output section with a connection node connected to another integrated circuit and including an output buffer circuit employing: a power supply; an output circuit having a first field-effect transistor and a second field-effect transistor which are connected in series between reference electric potentials by linking the drain electrode of the first field-effect transistor to the drain electrode of the second field-effect transistor through a connection point serving as an output node; an output control circuit for controlling an operation to put the output of the output control circuit in the state of a first level, the state of a second level or a high-impedance state; a substrate-voltage control circuit for connecting the substrate of the first field-effect transistor employed in the output circuit to the power supply of the output circuit when the power supply is put in a turned-on state; a gate-voltage control circuit for supplying a signal received from another integrated circuit connected to the output node of the output circuit to the gate electrode of the first field-effect transistor employed in the output circuit when the power supply of the output circuit has been put in a turned-off state and the signal received from the other integrated circuit has been in the state of the first level; and a signal supplying section configured to supply a signal received from another integrated circuit connected to the output node of the output circuit to the substrate of the first field-effect transistor employed in the output circuit when the power supply of the output buffer circuit has been put in a turned-off state and the signal received from the other integrated circuit has been in the state of the first level.

In accordance with the embodiments of the present invention, when the power supply of the output circuit is put in a turned-off state and a signal received from another integrated circuit connected to the output node of the output circuit is in the state of the first level (high level, for example), the signal supplying section supplies the first-level signal received from the other integrated circuit to the substrate of the first field-effect transistor employed in the output circuit.

In addition, when the power supply of the output buffer circuit is put in a turned-off state and a signal received from another integrated circuit connected to the output node of the output circuit is in the state of the first level, the gate-voltage control circuit supplies the first-level signal received from the other integrated circuit to the gate electrode of the first field-effect transistor employed in the output circuit.

In accordance with the embodiments of the present invention, it is possible to prevent the number of components from increasing, reduce the power consumption and prevent the LSI chip system from becoming complicated.

### BRIEF DESCRIPTION OF THE DRAWINGS

FIG. 1 is a diagram showing the configuration of an LSI (Large Scale Integrated) chip system according to a first embodiment of the present invention wherein a power supply of an output circuit employed in an LSI chip included in the chip system is put in a turned-on state;

FIG. 2 is a diagram showing the configuration of the LSI chip system according to the first embodiment of the present invention wherein the power supply of the output circuit employed in the LSI chip included in the chip system is put in a turned-off state;

FIG. 3 is a diagram showing the configuration of an LSI chip system according to a second embodiment of the present invention wherein a power supply of an output circuit employed in an LSI chip included in the chip system is put in a turned-on state;

FIG. 4 is a diagram showing the configuration of the LSI chip system according to the second embodiment of the present invention wherein the power supply of the output buffer circuit employed in the LSI chip included in the chip system is put in a turned-off state;

FIG. 5 is a circuit diagram showing the configuration of an LSI chip system including an LSI chip having an output buffer circuit according to a first typical concrete example of the present invention;

FIG. 6 is a circuit diagram showing the configuration of an LSI chip system including an LSI chip having an output buffer circuit according to a second typical concrete example of the present invention;

FIG. 7 is a circuit diagram showing the configuration of an LSI chip system including an LSI chip having an output buffer circuit according to a third typical concrete example of the present invention; and

FIG. 8 is a circuit diagram showing the configuration of an LSI chip system including an LSI chip having an output buffer circuit according to a fourth typical concrete example of the present invention.

### DETAILED DESCRIPTION OF THE PREFERRED EMBODIMENTS

Preferred embodiments of the present invention are explained by referring to diagrams as follows.

### First Embodiment

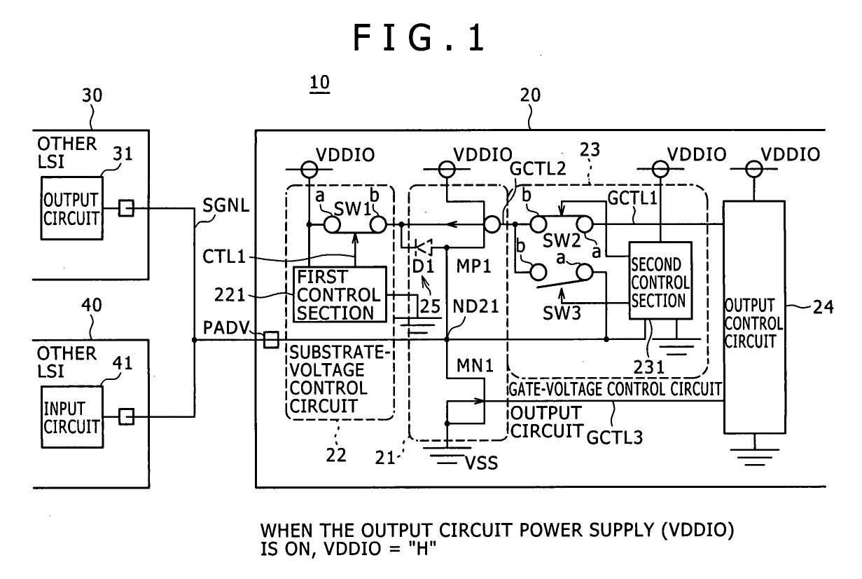

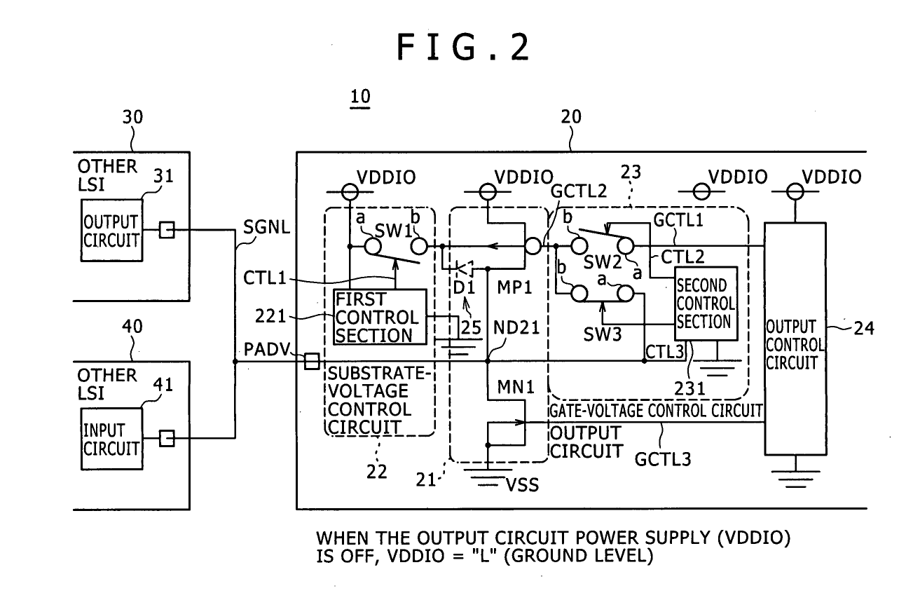

Each of FIGS. 1 and 2 is a diagram showing the configuration of an LSI (Large Scale Integrated) chip system (or an integrated circuit system) 10 according to a first embodiment of the present invention. To be more specific, FIG. 1 is a diagram showing the LSI chip system 10 with a power supply VDDIO of an output buffer circuit put in a turned-on state whereas FIG. 2 is a diagram showing the LSI chip system 10 with the power supply VDDIO put in a turned-off state. It is to be noted that, with the power supply VDDIO put in a turned-on state, the electric potential of the power supply VDDIO is set at a level higher than a ground level of 0 V. With the power supply VDDIO put in a turned-off state, on the other hand, the electric potential of the power supply VDDIO is set at the ground level of 0 V.

First of all, by referring to the diagram of FIG. 1, the following description begins with an explanation of the configuration of an output buffer circuit included in an LSI chip 20 employed in the LSI chip system 10 and the turned-on state of the power supply VDDIO.

As shown in the diagram of FIG. 1, the LSI chip system 10 includes the LSI chip 20 as well as other LSI chips 30 and 40. Input/output sections of the LSI chips 20, 30 and 40 are connected to each other by a signal line SGNL. To be more specific, the LSI chip 20 has an output circuit 21 included in the output section, the LSI chip 30 has an output circuit 31 included in the output section whereas the LSI chip 40 has an input circuit 41 included in the input section. These output sections of the LSI chips 20 and 30 and the input section of the LSI chip 40 are connected to each other by the signal line SGNL. In the following description, the output section is also referred to as an output buffer circuit.

As shown in the diagram of FIG. 1, the output section (or the output buffer circuit) of the LSI chip 20 employs an output circuit 21, a substrate-voltage control circuit 22, a gate-voltage control circuit 23, an output control circuit 24, a signal supplying circuit 25 and a connection pad PADV serving as a node connecting the LSI chip 20 with other LSI chips such as the LSI chip 30 and the LSI chip 40.

As shown in the diagram of FIG. 1, one signal line SGNL is connected to the output sections of 2 or more LSI chips such as the LSI chip 30 and the LSI chip 20 itself. In this case, signals generated by the output sections are shorted inadvertently to each other. In order to solve this problem, when the output section of a particular one of the LSI chips generates an output signal, each of the output sections of the other LSI chips is put in a Hi-Z (high-impedance) state with a timing with which the particular LSI chip generates the output signal.

The output circuit 21 has a PMOS (P-channel metal-oxide-semiconductor) transistor MP1 and an NMOS (N-channel metal-oxide-semiconductor) transistor MN1. The PMOS transistor MP1 and the NMOS transistor MN1 are connected in series between the power supply VDDIO and a reference electric potential VSS such as the ground electric potential GND through a connection point serving as an output node ND21. The PMOS transistor MP1 serves as a first field-effect transistor whereas the NMOS transistor MN1 serves as a second field-effect transistor. The source electrode of the PMOS transistor MP1 is connected to the power supply VDDIO whereas the source electrode of the NMOS transistor MN1 is connected to the reference electric potential VSS. The drain electrode of the PMOS transistor MP1 is connected to the drain electrode of the NMOS transistor MN1 through the output node ND21.

The substrate voltage of the PMOS transistor MP1 is controlled by the substrate-voltage control circuit 22 and the signal supplying circuit 25. The gate voltage of the PMOS transistor MP1 is controlled by the gate-voltage control circuit 23 through gate control lines GCTL1 and GCTL2 in accordance with control executed by the output control circuit 24. The gate voltage of the NMOS transistor MN1 is controlled by the output control circuit 24 through a gate control line GCTL3.

The substrate-voltage control circuit 22 employs a switch SW1 and a first control section 221.

A terminal a of the switch SW1 is connected to the power supply VDDIO and a terminal b of the switch SW1 is connected to the substrate of the PMOS transistor MP1 employed in the output circuit 21.

In accordance with the electric potential of the power supply VDDIO, the first control section 221 generates a control signal CTL1 for putting the switch SW1 in a turned-on or turned-off state. To put it in detail, when the power supply VDDIO is put in a turned-on state, the first control section 221 generates a control signal CTL1 for putting the switch SW1 in a turned-on state in order to electrically connect the substrate of the MOS transistor MP1 to the power supply VDDIO as shown in the diagram of FIG. 1.

The gate-voltage control circuit 23 employs switches SW2 and SW3 as well as a second control section 231.

A terminal a of the switch SW2 is connected to the output control circuit 24 by the first gate control line GCTL1 whereas a terminal b of the switch SW2 is connected to the gate electrode of the PMOS transistor MP1 of the output circuit 21 by the second gate control line GCTL2.

A terminal a of the switch SW3 is connected to the connection pad PADV through the output node ND21 whereas a terminal b of the switch SW3 is connected to the gate electrode of the PMOS transistor MP1 of the output circuit 21 by the second gate control line GCTL2.

In the same way as the first control section 221 employed in the substrate-voltage control circuit 22, in accordance with the electric potential of the power supply VDDIO, the second control section 231 employed in the gate-voltage control circuit 23 generates a control signal CTL2 for putting the switch SW2 in a turned-on or turned-off state and generates a control signal CTL3 for putting the switch SW3 in a turned-on or turned-off state. To put it in detail, when the power supply VDDIO is put in a turned-on state, the second control section 231 generates a control signal CTL2 for putting the switch SW2 in a turned-on state and generates a control signal CTL3 for putting the switch SW3 in a turned-off state as shown in the diagram of FIG. 1. With the switch SW2 put in a turned-on state, the output control circuit 24 supplies a control signal to the PMOS transistor MP1 by way of the switch SW2 through the gate control lines GCTL1 and GCTL2 and supplies a control signal to the NMOS transistor MN1 through the gate control line GCTL3 in order to control the PMOS transistor MP1 and the NMOS transistor MN1 to generate an output signal. In this state, the output circuit 31 employed in the LSI chip 30 connected to the connection pad PADV should be put in a Hi-Z state.

The output control circuit 24 sets the output of the output circuit 21 in the H, L or Hi-Z level in accordance with a control signal generated internally in the LSI chip 20. The H level also referred to as the first level is the level of a voltage generated by the power supply VDDIO whereas the L level also referred to as the second level is the level of the ground voltage VSS.

The output control circuit 24 is connected to the gate of the PMOS transistor MP1 by the first gate control line GCTL1, the switch SW2 and the second gate control line GCTL2.

When the power supply VDDIO is put in a turned-on state, each of the switch SW1 employed in the substrate-voltage control circuit 22 and the switch SW2 employed in the gate-voltage control circuit 23 is also put in a turned-on state but the switch SW3 employed in the gate-voltage control circuit 23 is put in a turned-off state as shown in the diagram of FIG. 1.

In the first embodiment, the signal supplying circuit 25 is configured as a PN diode D1 created between the drain area of the PMOS transistor MP1 employed in the output circuit 21 and the substrate of the PMOS transistor MP1 to serve as a diode for supplying a signal received from another LSI chip such as the LSI chip 30 to the substrate.

By referring to the diagram of FIG. 1, the above description has explained the configuration of an output buffer circuit included in an LSI chip 20 employed in the LSI chip system 10 and the turned-on state of the power supply VDDIO.

Next, by referring to a diagram of FIG. 2, the following description explains states in which sections employed in the output buffer circuit of the LSI chip 20 are put when the power supply VDDIO is put in a turned-off state.

When the power supply VDDIO is put in a turned-off state, each of the outputs of the output control circuit 24 is put in an indeterminate state. In this state, the first control section 221 employed in the substrate-voltage control circuit 22 executes control to put the switch SW1 in a turned-off state.

If the output circuit 31 employed in the LSI chip 30 connected to the connection pad PADV generates an output set at an H level at that time, the LSI chip 20 makes a transition to a state as described as follows. The output generated by the output circuit 31 at the H level and supplied to the connection pad PADV works as a forward-direction bias applied to the PN diode D1 which is created between the diffusion layer of the drain electrode serving as one of the terminals of the PMOS transistor MP1 and the substrate of the PMOS transistor MP1. Thus, the connection pad PADV is connected to the substrate of the PMOS transistor MP1 through the output node ND21, the drain electrode of the PMOS transistor MP1 and the PN diode D1.

The source electrode serving as the other terminal of the PMOS transistor MP1 is connected to the power supply VDDIO which happens to be in a turned-off state of pulling the power supply VDDIO to the ground level at that time. On the other hand, the connection pad PADV is connected to the output circuit 31 employed in the LSI chip 30.

Thus, in the case of an ordinary LSI chip, since the electric potential appearing on the gate electrode of the PMOS transistor MP1 is put in an indeterminate state, the PMOS transistor MP1 is put in a turned-on state causing a penetration current to flow between the output of another LSI chip such as the LSI chip 30 and the power supply VDDIO.

In the case of the first embodiment, on the other hand, the gate-voltage control circuit 23 executes control to put the switch SW2 in a turned-off state but put the switch SW3 in a turned-on state. Thus, the electric potential appearing on the gate electrode of the PMOS transistor MP1 is set at the same level as the output of the LSI chip 30, causing the PMOS transistor MP1 to enter a turned-off state. As a result, no penetration current flows between the output of another LSI chip such as the LSI chip 30 and the power supply VDDIO so that the power supply VDDIO can be sustained in a turned-off state of pulling the power supply VDDIO to the ground level without causing a problem while the LSI chip 30 is generating an output at the H level.

### Second Embodiment

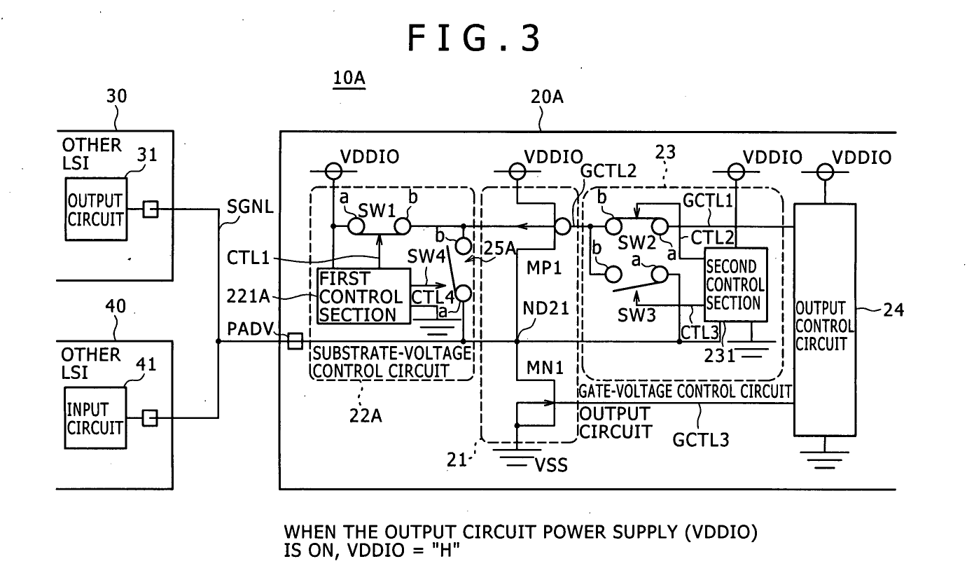

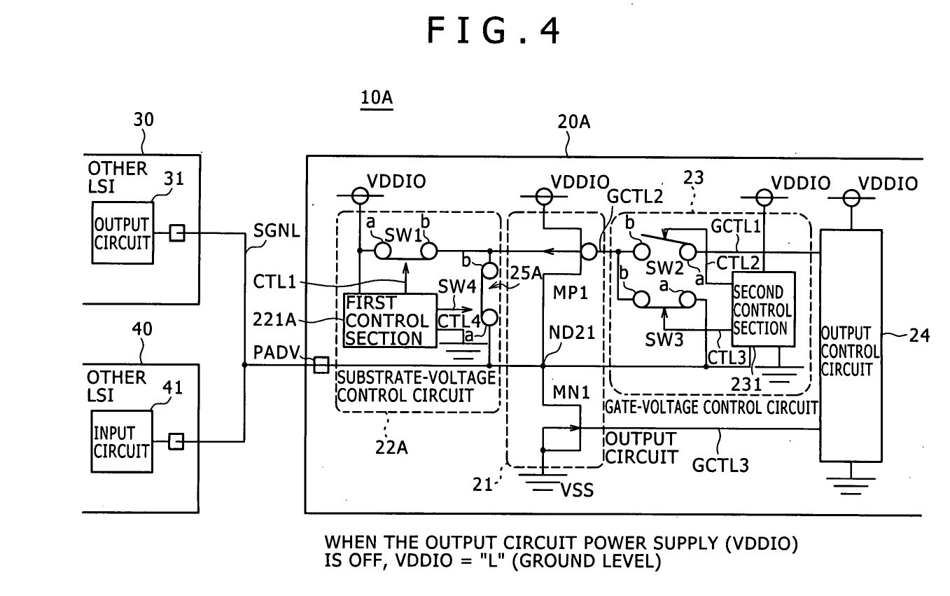

Each of FIGS. 3 and 4 is a diagram showing the configuration of an LSI (Large Scale Integrated) chip system 10A according to a second embodiment of the present invention. To be more specific, FIG. 3 is a diagram showing the LSI chip system 10A with a power supply VDDIO of an output buffer circuit put in a turned-on state whereas FIG. 4 is a diagram showing the LSI chip system 10A with the power supply VDDIO put in a turned-off state.

The LSI chip system 10A according to the second embodiment is different from the LSI chip system 10 according to the first embodiment in that, in place of the signal supplying circuit 25 employed in the LSI chip 20 of the LSI chip system 10, the LSI chip 20A of the LSI chip system 10A employs a signal supplying circuit 25A having a configuration different from the configuration of the signal supplying circuit 25 as described as follows. When the power supply VDDIO is put in a turned-off state, a switch SW4 serving as the signal supplying circuit 25A selectively connects the substrate of the PMOS transistor MP1 to the output node ND21 in order to supply an H-level signal received from another LSI chip such as the LSI chip 30 to the substrate of the PMOS transistor MP1.

In the case of the second embodiment, the signal supplying circuit 25A is the switch SW4 provided in a substrate-voltage control circuit 22A to serve as a switch which is driven by a first control section 221A employed in a substrate-voltage control circuit 22A of the LSI chip 20A.

Next, by referring to the diagram of FIG. 3, the following description explains states in which sections employed in the LSI chip 20A are put when the power supply VDDIO is put in a turned-on state.

As shown in the diagram of FIG. 3, the substrate-voltage control circuit 22A employs the switch SW1, the switch SW4 and the first control section 221A. A terminal a of the switch SW4 is connected to the output node ND21 and the connection pad PADV whereas a terminal b of the switch SW4 is connected to the substrate of the PMOS transistor MP1 employed in the output circuit 21.

The first control section 221A generates a control signal CTL1 for putting the switch SW1 in a turned-on or turned-off state and a control signal CTL4 for putting the switch SW4 in a turned-on or turned-off state. When the power supply VDDIO is put in a turned-on state, the first control section 221A generates the control signal CTL1 for putting the switch SW1 in a turned-on state in order to connect the substrate of the PMOS transistor MP1 to the power supply VDDIO, but generates the control signal CTL4 for putting the switch SW4 in a turned-off state as shown in the diagram of FIG. 3.

In the same way as the first control section 221A employed in the substrate-voltage control circuit 22A, the second control section 231 employed in the gate-voltage control circuit 23 generates a control signal CTL2 for putting the switch SW2 in a turned-on or turned-off state and generates a control signal CTL3 for putting the switch SW3 in a turned-on or turned-off state. To put it in detail, when the power supply VDDIO is put in a turned-on state, the first control section 221 generates a control signal CTL2 for putting the switch SW2 in a turned-on state and generates a control signal CTL3 for putting the switch SW3 in a turned-off state as shown in the diagram of FIG. 3. With the switch SW2 put in a turned-on state, the output control circuit 24 supplies a control signal to the PMOS transistor MP1 by way of the switch SW2 through the gate control lines GCTL1 and GCTL2 and supplies a control signal to the NMOS transistor MN1 through the gate control line GCTL3 in order to control the PMOS transistor MP1 and the NMOS transistor MN1 to generate an output signal. In this state, the output circuit 31 employed in the LSI chip 30 connected to the connection pad PADV should be put in a Hi-Z state.

Next, by referring to the diagram of FIG. 4, the following description explains states in which sections employed in the LSI chip 20A are put when the power supply VDDIO is put in a turned-off state.

When the power supply VDDIO is put in a turned-off state, each of the outputs of the output control circuit 24 is put in an indeterminate state. In this state, the first control section 221A employed in the substrate-voltage control circuit 22A executes control to put the switch SW1 in a turned-off state. In addition, the first control section 221A employed in the substrate-voltage control circuit 22A executes control to put the switch SW4 in a turned-on state.

If the output circuit 31 employed in the LSI chip 30 connected to the connection pad PADV generates an output set at an H level at that time, the output appears on the connection pad PADV because the connection pad PADV is connected to the output circuit 31. Thus, the output set at an H level is supplied to the substrate of the PMOS transistor MP1.

The source electrode serving as the other terminal of the PMOS transistor MP1 is connected to the power supply VDDIO which happens to be in a turned-off state of pulling the power supply VDDIO to the ground level at that time. On the other hand, the connection pad PADV is connected to the output circuit 31 employed in the LSI chip 30.

Thus, in the case of an ordinary LSI chip, since the electric potential appearing on the gate electrode of the PMOS transistor MP1 is put in an indeterminate state, the PMOS transistor MP1 is put in a turned-on state causing a penetration current to flow between the output of another LSI chip such as the LSI chip 30 and the power supply VDDIO.

In the case of the second embodiment, on the other hand, the gate-voltage control circuit 23 executes control to put the switch SW2 in a turned-off state but put the switch SW3 in a turned-on state. Thus, the electric potential appearing on the gate electrode of the PMOS transistor MP1 is set at the same level as the output of the LSI chip 30, causing the PMOS transistor MP1 to enter a turned-off state. As a result, no penetration current flows between the output of another LSI chip such as the LSI chip 30 and the power supply VDDIO so that the power supply VDDIO can be sustained in a turned-off state of pulling the power supply VDDIO to the ground level without causing a problem while the LSI chip 30 is generating an output at the H level.

So far, the basic configuration of the output buffer circuit has been explained. Next, four typical concrete examples of the embodiments of the present invention are explained. It is to be noted that, in order to make the following description easy to understand, in the four typical concrete examples of the embodiments, sections identical with their respective counterparts shown in the diagrams of FIGS. 1 to 4 are denoted by the same reference numerals and the same reference notations as the counterparts.

### FIRST TYPICAL CONCRETE EXAMPLE

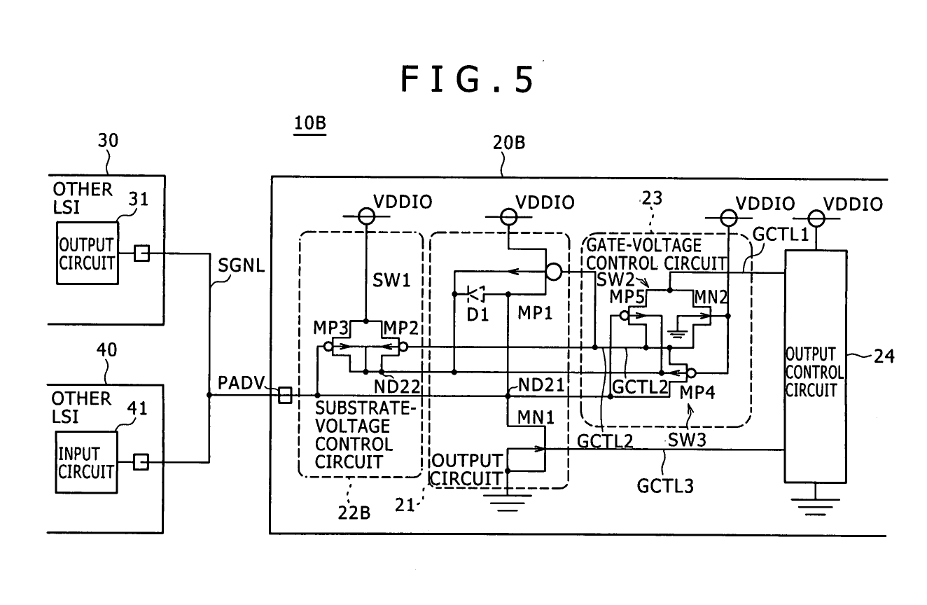

FIG. 5 is a circuit diagram showing the configuration of an LSI (Large Scale Integration) chip system 10B including a LSI chip 20B having an output buffer circuit according to a first typical concrete example of the present invention. The circuit diagram of FIG. 5 shows the first typical concrete example for the output buffer circuits shown in the diagrams of FIGS. 1 and 2.

As shown in the circuit diagram of FIG. 5, the substrate-voltage control circuit 22B is configured to employ PMOS transistors MP2 and MP3.

The source electrodes of the PMOS transistors MP2 and MP3 are connected to the power supply VDDIO. The drain electrodes of the PMOS transistors MP2 and MP3 and the substrates of the PMOS transistors MP2 and MP3 are connected to a connection node ND22 which is connected to the substrate of the PMOS transistor MP1 employed in the output circuit 21. The gate electrode of the PMOS transistor MP2 is connected to a second gate control line GCTL2 of a gate-voltage control circuit 23B whereas the gate electrode of the PMOS transistor MP3 is connected to the connection pad PADV.

The gate-voltage control circuit 23B is configured to employ PMOS transistors MP4 and MP5 as well as an NMOS transistor MN2.

The source electrode of the PMOS transistor MP5 and the drain electrode of the NMOS transistor MN2 are connected to a first gate control line GCTL1 of the output control circuit 24 whereas the drain electrode of the PMOS transistor MP5 and the source electrode of the NMOS transistor MN2 are connected to the second gate control line GCTL2 of the gate-voltage control circuit 23B. The second gate control line GCTL2 is also connected the gate electrode of the PMOS transistor MP1 employed in the output circuit 21 and the gate electrode of the PMOS transistor MP2 employed in the substrate-voltage control circuit 22B. The substrate of the NMOS transistor MN2 is connected to the ground.

The drain electrode of the PMOS transistor MP4 is connected to the output node ND21 and the connection pad PADV. The gate electrode of the PMOS transistor MP5 is also connected to the output node ND21 and the connection pad PADV. The gate electrodes of the NMOS transistor MN2 and the PMOS transistor MP4 are connected to the power supply VDDIO.

First of all, the following description explains states in which sections employed in the output buffer circuit are put when the power supply VDDIO is put in a turned-on state.

When the output of the output circuit 21 is set at the L level, the electric potential appearing on the gate electrode of the PMOS transistor MP3 employed in the substrate-voltage control circuit 22B is also set at the L level, connecting the substrate of the PMOS transistor MP3 to the power supply VDDIO. Thus, the electric potential appearing on the substrate of the PMOS transistor MP3 is set at the level of the power supply VDDIO.

Since the PMOS transistor MP5 has been put in a turned-on state, the gate-voltage control circuit 23B transmits a VDDIO-level signal generated by the output control circuit 24 to the gate electrode of the PMOS transistor MP1.

When the output of the output circuit 21 is set at the H level, the electric potential appearing on the gate electrode of the PMOS transistor MP1 is set at the L level and the electric potential appearing on gate electrode of the PMOS transistor MP2 is also set at the L level. Thus, the substrates of the PMOS transistors MP1 and MP2 are connected to the power supply VDDIO. As a result, the electric potentials appearing on the substrates of the PMOS transistors MP1 and MP2 are set at the level of the power supply VDDIO.

Since the NMOS transistor MN2 has been put in a turned-on state, the gate-voltage control circuit 23B transmits a ground-level signal generated by the output control circuit 24 to the gate electrode of the PMOS transistor MP1.

In addition, when the power supply VDDIO is put in a turned-on state, the PMOS transistor MP4 is put in a turned-off state. Thus, the electric potential appearing on the output node ND21 of the output circuit 21 and the connection pad PADV can be separated from the electric potential appearing on the gate electrode of the PMOS transistor MP1.

Next, the following description explains states in which sections employed in the output buffer circuit are put when the power supply VDDIO is put in a turned-off state.

Since the power supply VDDIO is put in a turned-off state, the gate electrodes of the PMOS transistor MP4 and the NMOS transistor MN2 which are employed in the gate-voltage control circuit 23B are set at the ground level. In this state, the PMOS transistor MP4 is put in a turned-on state whereas the NMOS transistor MN2 is put in a turned-off state.

The electric potential appearing on the gate electrode of the PMOS transistor MP5 is the electric potential appearing on the connection pad PADV. Since the PMOS transistor MP4 has been put in a turned-on state, the electric potential appearing on the drain area of the PMOS transistor MP5 becomes equal to the electric potential appearing on the connection pad PADV, putting the PMOS transistor MP5 in the turned-off state.

Thus, since each of the NMOS transistor MN2 and the PMOS transistor MP5 has been put in a turned-off state, a current flowing to the output control circuit 24 is blocked and it is possible to prevent a penetration current from flowing between the electric potential appearing on the connection pad PADV connected to the output circuit 31 employed in the LSI chip 30 and the power supply VDDIO of the output buffer circuit.

In the substrate-voltage control circuit 22B, the electric potential appearing on the gate electrode of the PMOS transistor MP3 becomes equal to the electric potential appearing on the connection pad PADV and the electric potential appearing on the gate electrode of the PMOS transistor MP2 also becomes equal to the electric potential appearing on the connection pad PADV because the PMOS transistor MP4 has been put in a turned-on state.

At that time, the electric potentials appearing on the drain electrodes of the PMOS transistors MP2 and MP3, that is, the electric potentials appearing on the substrates of the PMOS transistors MP1, MP2, MP3, MP4 and MP5, are determined as follows.

A parasitic PN diode is formed between the drain area (serving as the output portion) and substrate of each of the PMOS transistors MP1, MP4 and MP5. In the circuit diagram of FIG. 5, a parasitic PN diode D1 of the PMOS transistor MP1 is shown as a representative. In actuality, however, the parasitic PN diodes of the PMOS transistors MP4 and MP5 also exist but are not shown in the circuit diagram of FIG. 5. Thus, the substrate of each of the PMOS transistors MP1, MP4 and MP5 is electrically connected to the connection pad PADV. As a result, an electric potential of PADV-diode Vth is supplied to the substrate of each of the PMOS transistors MP1, MP4 and MP5. Therefore, currents flowing from the PMOS transistors MP2 and MP3 to the power supply VDDIO are blocked. Since the power supply VDDIO has been put in a turned-off state, the power supply VDDIO is at the ground level.

In addition, since the PMOS transistor MP4 employed in the gate-voltage control circuit 23B is put in a turned-on state, the electric potential appearing on the gate electrode of the PMOS transistor MP1 employed in the output circuit 21 becomes equal to the electric potential appearing on the connection pad PADV. As result, the electric potential appearing on the connection pad PADV is supplied to the gate and drain electrodes of the PMOS transistor MP1 whereas the electric potential of PADV-diode Vth is supplied to the substrate of the PMOS transistor MP1. Accordingly, it is possible to prevent a penetration current from flowing between the electric potential appearing on the connection pad PADV connected to the output circuit 31 employed in the LSI chip 30 and the power supply VDDIO of the output buffer circuit.

### SECOND TYPICAL CONCRETE EXAMPLE

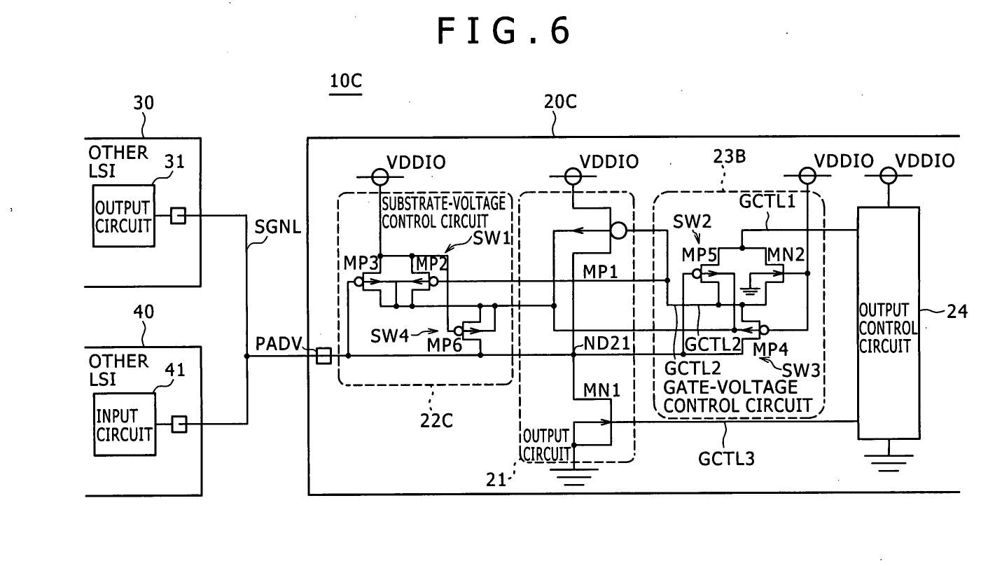

FIG. 6 is a circuit diagram showing the configuration of an LSI (Large Scale Integration) chip system 10C including an LSI chip 20C having an output buffer circuit according to a second typical concrete example of the present invention. The circuit diagram of FIG. 6 shows the second typical concrete example for the output buffer circuits shown in the diagrams of FIGS. 3 and 4. In the configuration shown in the circuit diagram of FIG. 6, sections identical with their respective counterparts included in the configuration shown in the circuit diagram of FIG. 5 are denoted by the same reference numerals as the counterparts.

As shown in the circuit diagram of FIG. 6, the substrate-voltage control circuit 22C has a PMOS transistor MP6 in addition to the PMOS transistors MP2 and MP3 which are included in the substrate-voltage control circuit 22B of the configuration shown in the circuit diagram of FIG. 5.

As shown in the circuit diagram of FIG. 6, the source electrode of the PMOS transistor MP6 is connected to the substrate of the PMOS transistor MP6 itself as well as the substrates of the PMOS transistors MP1, MP2, MP3, MP4 and MP5. The drain electrode of the PMOS transistor MP6 is connected to the connection pad PADV and the output node ND21 of the output circuit 21.

The rest of the configuration of the second typical concrete example is identical with the configuration of the first typical concrete example shown in the circuit diagram of FIG. 5.

First of all, the following description explains states in which sections employed in the output buffer circuit are put when the power supply VDDIO is put in a turned-on state.

When the output of the output circuit 21 is set at the L level, the electric potential appearing on the gate electrode of the PMOS transistor MP3 employed in the substrate-voltage control circuit 22C is also set at the L level, connecting the substrate of the PMOS transistor MP3 to the power supply VDDIO. Thus, the electric potential appearing on the substrate of the PMOS transistor MP3 is set at the level of the power supply VDDIO.

Since the PMOS transistor MP5 has been put in a turned-on state, the gate-voltage control circuit 23B transmits a VDDIO-level signal generated by the output control circuit 24 to the gate electrode of the PMOS transistor MP1.

When the output of the output circuit 21 is set at the H level, the electric potential appearing on the gate electrode of the PMOS transistor MP1 is set at the L level and the electric potential appearing on gate electrode of the PMOS transistor MP2 is also set at the L level. Thus, the substrates of the PMOS transistors MP1 and MP2 are connected to the power supply VDDIO. As a result, the electric potentials appearing on the substrates of the PMOS transistors MP1 and MP2 are set at the level of the power supply VDDIO.

Since the NMOS transistor MN2 has been put in a turned-on state, the gate-voltage control circuit 23B transmits a ground-level signal generated by the output control circuit 24 to the gate electrode of the PMOS transistor MP1.

In addition, when the power supply VDDIO is put in a turned-on state, each of the PMOS transistor MP4 and the PMOS transistor MP6 is put in a turned-off state. Thus, the electric potential appearing on the output node ND21 and the connection pad PADV can be separated from the electric potential appearing on the gate electrode of the PMOS transistor MP1.

Next, the following description explains states in which sections employed in the output buffer circuit are put when the power supply VDDIO is put in a turned-off state.

Since the power supply VDDIO has been put in a turned-off state, the gate electrodes of the PMOS transistor MP4 and the NMOS transistor MN2 which are employed in the gate-voltage control circuit 23B are set at the ground level. In this state, the PMOS transistor MP4 is put in a turned-on state whereas the NMOS transistor MN2 is put in a turned-off state.

The electric potential appearing on the gate electrode of the PMOS transistor MP5 is the electric potential appearing on the connection pad PADV. Since the PMOS transistor MP4 has been put in a turned-on state, the electric potential appearing on the drain area of the PMOS transistor MP5 becomes equal to the electric potential appearing on the connection pad PADV, putting the PMOS transistor MP5 in the turned-off state.

Thus, since each of the NMOS transistor MN2 and the PMOS transistor MP5 has been put in a turned-off state, a current flowing to the output control circuit 24 is blocked and it is possible to prevent a penetration current from flowing between the electric potential appearing on the connection pad PADV connected to the output circuit 31 employed in the LSI chip 30 and the power supply VDDIO of the output buffer circuit.

In the substrate-voltage control circuit 22C, the electric potential appearing on the gate electrode of the PMOS transistor MP3 becomes equal to the electric potential appearing on the connection pad PADV and the electric potential appearing on the gate electrode of the PMOS transistor MP2 also becomes equal to the electric potential appearing on the connection pad PADV because the PMOS transistor MP4 has been put in a turned-on state.

At that time, the electric potentials appearing on the drain electrodes of the PMOS transistors MP2 and MP3, that is, the electric potentials appearing on the substrates of the PMOS transistors MP1, MP2, MP3, MP4 and MP5, are each set at a level putting the PMOS transistor MP6 in a turned-on state because the electric potential appearing on the gate electrode of the PMOS transistor MP6 has been set at the ground level. As a result, the connection pad PADV is connected to the substrates of the PMOS transistors MP1, MP2, MP3, MP4 and MP5 by the PMOS transistor MP6 so that each of the electric potentials appearing on the substrates of the PMOS transistors MP1, MP2, MP3, MP4 and MP5 becomes equal to the electric potential appearing on the connection pad PADV.

Therefore, currents flowing from the PMOS transistors MP2 and MP3 to the power supply VDDIO are blocked. Since the power supply VDDIO has been put in a turned-off state, the power supply VDDIO is set at the ground level.

In addition, since the PMOS transistor MP4 employed in the gate-voltage control circuit 23B has been put in a turned-on state, the electric potential appearing on the gate electrode of the PMOS transistor MP1 employed in the output circuit 21 becomes equal to the electric potential appearing on the connection pad PADV. As result, the electric potential appearing on the connection pad PADV is supplied to the gate and drain electrodes of the PMOS transistor MP1 as well as supplied to the substrate of the PMOS transistor MP1. Accordingly, it is possible to prevent a penetration current from flowing between the electric potential appearing on the connection pad PADV connected to the output circuit 31 employed in the LSI chip 30 and the power supply VDDIO of the output buffer circuit.

### THIRD TYPICAL CONCRETE EXAMPLE

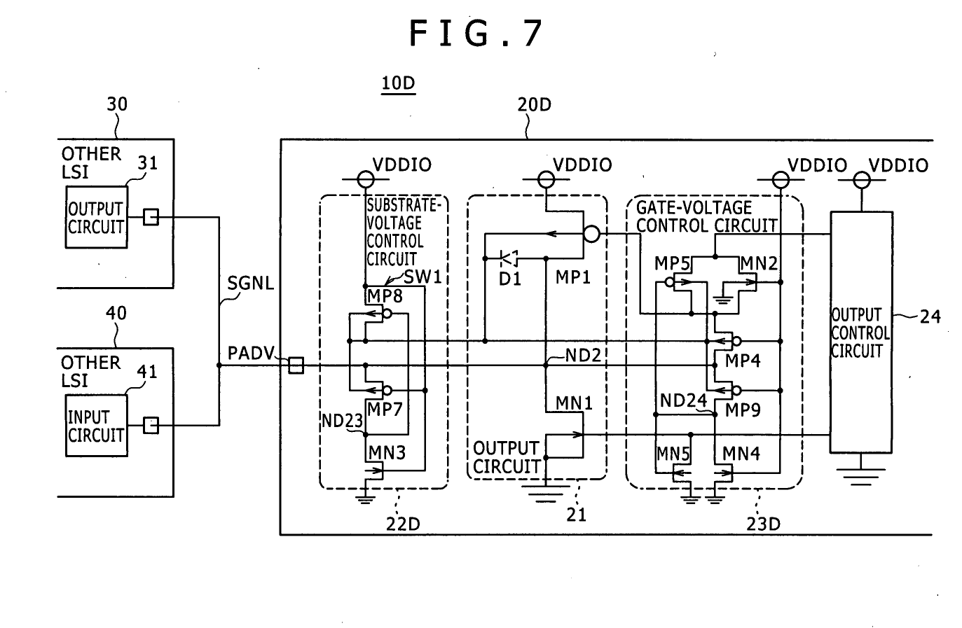

FIG. 7 is a circuit diagram showing the configuration of an LSI (Large Scale Integration) chip system 10D including an LSI chip 20D having an output buffer circuit according to a third typical concrete example of the present invention. The LSI chip 20D shown in the circuit diagram of FIG. 7 is a typical example different from the LSI chip 20B shown in the circuit diagram of FIG. 5 and has an output buffer circuit corresponding to the output buffer circuits shown in the diagrams of FIGS. 1 and 2. In the configuration shown in the circuit diagram of FIG. 7, sections identical with their respective counterparts included in the configuration shown in the circuit diagram of FIG. 5 are denoted by the same reference numerals as the counterparts.

As shown in the circuit diagram of FIG. 7, the substrate-voltage control circuit 22D employs PMOS transistors MP7 and MP8 as well as an NMOS transistor MN3. It is to be noted that the PMOS transistor MP8 corresponds to the third field-effect transistor.

The source electrode of the PMOS transistor MP7 is connected to the connection pad PADV and the output node ND21 of the output circuit 21 whereas the drain electrode of the PMOS transistor MP7 is connected to the drain electrode of the NMOS transistor MN3 through a connection node ND23. The source electrode of the NMOS transistor MN3 is connected to the reference electric potential VSS. The connection node ND23 connecting the drain electrodes of the PMOS transistor MP7 and the NMOS transistor MN3 to each other is connected to the gate electrode of the PMOS transistor MP8. The gate electrodes of the PMOS transistor MP7 and the NMOS transistor MN3 are connected to the power supply VDDIO.

The source electrode of the PMOS transistor MP8 is also connected to the power supply VDDIO. The drain electrode and substrate of the PMOS transistor MP8 are connected to the substrates of the PMOS transistors MP1, MP4, MP5, MP7 and MP9.

The gate-voltage control circuit 23D employs a PMOS transistor MP9 and NMOS transistors MN4 and MN5 in addition to the PMOS transistors MP4 and MP5 and the NMOS transistor MN2. It is to be noted that the PMOS transistor MP5 corresponds to the fourth field-effect transistor whereas the PMOS transistor MP4 corresponds to the fifth field-effect transistor.

The source electrode of the PMOS transistor MP9 is connected to the connection pad PADV and the output node ND21 of the output circuit 21 whereas the drain electrode of the PMOS transistor MP9 is connected to the drain electrode of the NMOS transistor MN4 through a connection node ND24. The connection node ND24 connecting the drain electrodes of the PMOS transistor MP9 and the NMOS transistor MN4 to each other is connected to the gate electrodes of the PMOS transistor MP5 and the NMOS transistor MN5.

The source electrodes of the NMOS transistors MN4 and MN5 are connected to the reference electric potential VSS. The drain electrode of the PMOS transistor MP5 is connected to the gate electrode of the NMOS transistor MN1 employed in the output circuit 21.

The gate electrodes of the PMOS transistor MP9 and the NMOS transistor MN4 are connected to the power supply VDDIO.

The substrate of the PMOS transistor MP9 is connected to the substrates of the PMOS transistors MP1, MP4, MP5 and MP7.

First of all, the following description explains states in which sections employed in the output buffer circuit are put when the power supply VDDIO is put in a turned-on state.

In the substrate-voltage control circuit 22D, the electric potential appearing on the gate electrode of the NMOS transistor MN3 is set at the level of the electric potential generated by the power supply VDDIO. Thus, the NMOS transistor MN3 is put in a turned-on state. With the NMOS transistor MN3 put in a turned-on state, the electric potential appearing on the gate electrode of the PMOS transistor MP8 becomes equal to the ground level. As a result, the power supply VDDIO is connected to the substrate of the PMOS transistor MP8 so that the electric potential appearing on the substrate of the PMOS transistor MP8 becomes equal to the level of the power supply VDDIO.

In the gate-voltage control circuit 23D, each of the NMOS transistors MN2 and MN4 has been put in a turned-on state so that the electric potential appearing on the gate electrode of the PMOS transistor MP5 becomes equal to the ground level, putting the PMOS transistor MP5 in a turned-on state. In this state, the output control circuit 24 supplies a signal at the level of the electric potential generated by the power supply VDDIO to the gate electrode of the PMOS transistor MP1 and a signal at the ground level to the gate electrode of the NMOS transistor MN1.

At that time, the electric potential appearing on the gate of each of the PMOS transistors MP4, MP9 and MP7 is set at the level of the electric potential generated by the VDDIO whereas the electric potential appearing on the gate of the NMOS transistor MN5 is set at the ground level. Thus, each of the PMOS transistors MP4, MP9 and MP7 and the NMOS transistor MN5 is put in a turned-off state. As a result, the electric potential appearing on the connection pad PADV of the output buffer current can be separated from the electric potentials appearing on the gate electrodes of the PMOS transistor MP1 and the NMOS transistor MN1.

Next, the following description explains states in which sections employed in the output buffer circuit are put when the power supply VDDIO is put in a turned-off state.

In the gate-voltage control circuit 23D, the gate electrode of each of the PMOS transistors MP4 and MP9 as well as the NMOS transistors MN2 and MN4 is set at the ground level because the power supply VDDIO has been set in a turned-off state. The PMOS transistors MP4 and MP9 are put in a turned-on state whereas the NMOS transistors MN2 and MN4 are put in a turned-off state.

Since the PMOS transistor MP4 has been put in a turned-on state, the electric potential appearing in the drain area of the PMOS transistor MP5 becomes equal to the electric potential appearing on the connection pad PADV. In addition, since the PMOS transistor MP9 has been put in a turned-on state, the electric potential appearing on the gate electrode of the PMOS transistor MP5 becomes equal to the electric potential appearing on the connection pad PADV. Thus, the PMOS transistor MP5 is put in a turned-off state.

Therefore, since each of the NMOS transistor MN2 and the PMOS transistor MP5 has been put in a turned-off state, a current flowing to the output control circuit 24 is blocked. Accordingly, it is possible to prevent a penetration current from flowing between the electric potential appearing on the connection pad PADV connected to the output circuit 31 employed in the LSI chip 30 and the power supply VDDIO of the output buffer circuit.

In addition, since the electric potential appearing on the gate electrode of the NMOS transistor MN5 becomes equal to the electric potential appearing on the connection pad PADV, if the electric potential appearing on the connection pad PADV rises to a level capable of putting the NMOS transistor MN5 in a turned-on state, the electric potential appearing on the gate electrode of the NMOS transistor MN1 employed in the output circuit 21 can be controlled to become equal to the ground level. As a result, no penetration current flows between the electric potential appearing on the connection pad PADV connected to the output circuit 31 employed in the LSI chip 30 and the ground of the output buffer circuit.

In the substrate-voltage control circuit 22D, the electric potential appearing on the gate electrode of the PMOS transistor MP7 is set at the ground level, putting the PMOS transistor MP7 in a turned-on state so that the electric potential appearing on the gate electrode of the PMOS transistor MP8 becomes equal to the electric potential appearing on the connection pad PADV.

At that time, the electric potential appearing on the drain electrodes of the PMOS transistor MP8, that is, the electric potentials appearing on the substrates of the PMOS transistors MP1, MP4, MP5, MP9, MP7 and MP8, are determined as follows.

A parasitic PN diode is formed between the drain area (serving as the output portion) and substrate of each of the PMOS transistors MP1, MP4, MP5, MP9 and MP7. In the circuit diagram of FIG. 7, a parasitic PN diode D1 of the PMOS transistor MP1 is shown as a representative. In actuality, however, the parasitic PN diodes of the PMOS transistors MP4, MP5, MP9 and MP7 also exist but are not shown in the circuit diagram of FIG. 7. Thus, the substrate of each of the PMOS transistors MP1, MP4, MP5, MP9 and MP7 is electrically connected to the connection pad PADV. As a result, an electric potential of PADV-diode Vth is supplied to the substrate of each of the PMOS transistors MP1, MP4, MP5, MP9 and MP7. Therefore, a current flowing from the PMOS transistor MP8 to the power supply VDDIO is blocked. Since the power supply VDDIO has been put in a turned-off state, the power supply VDDIO is set at the ground level.

In addition, since the PMOS transistor MP4 employed in the gate-voltage control circuit 23D is put in a turned-on state, the electric potential appearing on the gate electrode of the PMOS transistor MP1 employed in output circuit 21 becomes equal to the electric potential appearing on the connection pad PADV. As a result, the electric potential appearing on each of the gate and drain electrodes of the PMOS transistor MP1 becomes equal to the electric potential appearing on the connection pad PADV whereas the electric potential of PADV-diode Vth is supplied to the substrate of the PMOS transistor MP1.

Accordingly, no penetration current flows between the electric potential appearing on the connection pad PADV connected to the output circuit 31 employed in the LSI chip 30 and the power supply VDDIO of the output buffer circuit.

### FOURTH TYPICAL CONCRETE EXAMPLE

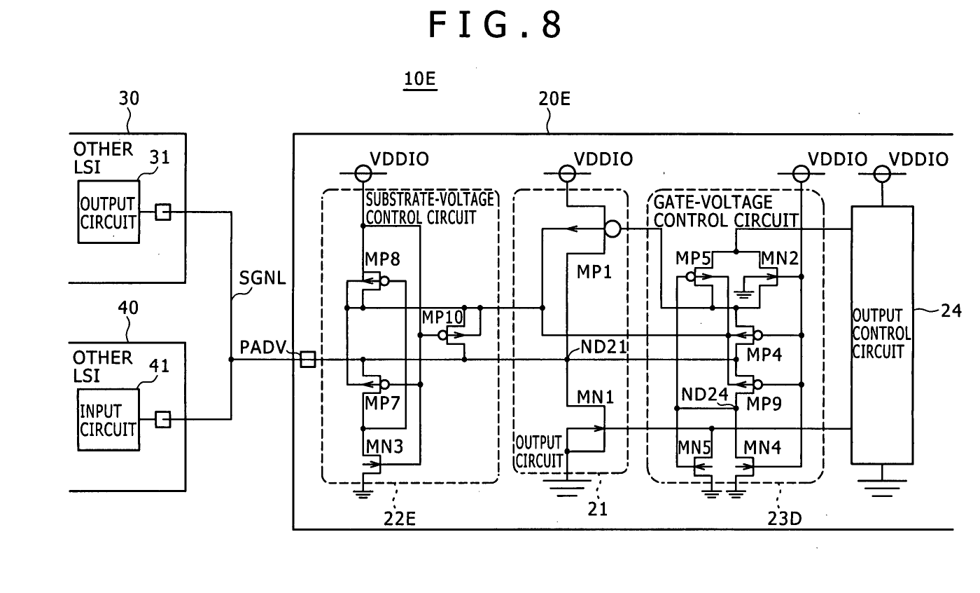

FIG. 8 is a circuit diagram showing the configuration of an LSI (Large Scale Integration) chip system 10E including a LSI chip 20E having an output buffer circuit according to a fourth typical concrete example of the present invention. The LSI chip 20E shown in the circuit diagram of FIG. 8 is a typical example different from the LSI chip 20C shown in the circuit diagram of FIG. 6 and has an output buffer circuit corresponding to the output buffer circuits shown in the diagrams of FIGS. 3 and 4. In the configuration shown in the circuit diagram of FIG. 8, sections identical with their respective counterparts included in the configuration shown in the circuit diagram of FIG. 6 are denoted by the same reference numerals as the counterparts.

As shown in the circuit diagram of FIG. 8, the substrate-voltage control circuit 22E employs a PMOS transistor MP10 in addition to the PMOS transistors MP7 and MP8 as well as an NMOS transistor MN3. It is to be noted that the PMOS transistor MP10 corresponds to the sixth field-effect transistor.

The gate electrode of the PMOS transistor MP10 is connected to the power supply VDDIO whereas the source electrode of the PMOS transistor MP10 is connected to the connection pad PAVD and the output node ND21 of the output circuit 21. The source electrode and substrate of the PMOS transistor MP10 are connected to the substrate of each of the PMOS transistors MP1, MP4, MP5, MP7 and MP9.

First of all, the following description explains states in which sections employed in the output buffer circuit are put when the power supply VDDIO is put in a turned-on state.

In the substrate-voltage control circuit 22E, the electric potential appearing on the gate electrode of the NMOS transistor MN3 is set at the level of the electric potential generated by the power supply VDDIO. Thus, the NMOS transistor MN3 is put in a turned-on state. With the NMOS transistor MN3 put in a turned-on state, the electric potential appearing on the gate electrode of the PMOS transistor MP8 becomes equal to the ground level. Thus, the power supply VDDIO is connected to the substrate of the PMOS transistor MP8 so that the electric potential appearing on the substrate becomes equal to the level of the electric potential generated by the power supply VDDIO.

In the gate-voltage control circuit 23D, each of the PMOS transistors MN2 and MN4 is put in a turned-on state. Thus, the electric potential appearing on the gate electrode of the PMOS transistor MP5 becomes equal to the ground level, putting the PMOS transistor MP5 in a turned-on state.

A VDDIO-level signal generated by the output control circuit 24 is transmitted to the gate electrode of the PMOS transistor MP1 whereas a ground-level signal generated by the output control circuit 24 is transmitted to the gate electrode of the NMOS transistor MN1.

At that time, since the electric potential appearing on the gate electrode of each of the PMOS transistors MP4, MP9 and MP7 has been set at the level of the electric potential generated by the power supply VDDIO and the electric potential appearing on the gate electrode of the PMOS transistor MP5 has become equal to the ground level, the PMOS transistor MP5 is put in a turned-on state. Thus, each of the PMOS transistors MP4, MP9 and MP7 and the NMOS transistor MN5 is put in a turned-off state. As a result, the electric potential appearing on the connection pad PADV of the output buffer circuit can be separated from the electric potentials appearing on the gate electrodes of the PMOS transistor MP1 and the NMOS transistor MN1.

Next, the following description explains states in which sections employed in the output buffer circuit are put when the power supply VDDIO is put in a turned-off state.

Since the power supply VDDIO has been set in a turned-off state, in the gate-voltage control circuit 23D, the gate electrode of each of the PMOS transistors MP4 and MP9 as well as the NMOS transistors MN2 and MN4 is set at the ground level, putting the PMOS transistors MP4 and MP9 in a turned-on state and the NMOS transistors MN2 and MN4 in a turned-off state.

Since the PMOS transistor MP4 is put in a turned-on state, the electric potential appearing in the drain area of the PMOS transistor MP5 becomes equal to the electric potential appearing on the connection pad PADV. By the same token, since the PMOS transistor MP9 is put in a turned-on state, the electric potential appearing on the gate electrode of the PMOS transistor MP5 becomes equal to the electric potential appearing on the connection pad PADV. As a result, the PMOS transistor MP5 is put in a turned-off state.

Thus, since each of the NMOS transistor MN2 and the PMOS transistor MP5 is put in a turned-off state, a current flowing to the output control circuit 24 is blocked. Accordingly, it is possible to prevent a penetration current from flowing between the electric potential appearing on the connection pad PADV connected to the output circuit 31 employed in the LSI chip 30 and the power supply VDDIO of the output buffer circuit.

In addition, since the electric potential appearing on the gate electrode of the NMOS transistor MN5 becomes equal to the electric potential appearing on the connection pad PADV, if the electric potential appearing on the connection pad PADV rises to a level capable of putting the NMOS transistor MN5 in a turned-on state, the electric potential appearing on the gate electrode of the NMOS transistor MN1 employed in the output circuit 21 can be controlled to become equal to the ground level. In addition, no penetration current flows between the electric potential appearing on the connection pad PADV connected to the output circuit 31 employed in the LSI chip 30 and the ground of the output buffer circuit.

In the substrate-voltage control circuit 22E, the electric potential appearing on the gate electrode of each of the PMOS transistors MP7 and MP10 is set at the ground level, putting the PMOS transistor MP7 in a turned-on state so that the electric potential appearing on the gate electrode of the PMOS transistor MP8 becomes equal to the electric potential appearing on the connection pad PADV.

At that time, the electric potentials appearing on the drain electrode of the PMOS transistor MP8, that is, the electric potentials appearing on the substrates of the PMOS transistors MP1, MP4, MP5, MP9, MP7, MP8 and MP10, are each set at the PADV level because the PMOS transistor MP10 has been put in a turned-on state connecting the substrates to the connection pad PADV.

In addition, since the PMOS transistor MP4 employed in the gate-voltage control circuit 23D is put in a turned-on state, the electric potential appearing on the gate electrode of the PMOS transistor MP1 employed in the output circuit 21 becomes equal to the electric potential appearing on the connection pad PADV so that the electric potentials appearing on the gate and drain electrodes as well as substrate of the PMOS transistor MP1 become equal to the electric potential appearing on the connection pad PADV.

As a result, no penetration current flows between the electric potential appearing on the connection pad PADV connected to the output circuit 31 employed in the LSI chip 30 and the power supply VDDIO of the output buffer circuit.

As described above, the embodiments of the present invention have the following effects.

In an LSI chip system including a number of LSI chips (or LSI circuits), there is no extra circuit each serving as an interface between an LSI chip already put in a turned-on state and an LSI chip to be put in a turned-off state. Thus, the embodiments of the present invention are capable of contributing to reduction of the number of components used in each of the LSI chips. As a result, it is possible to reduce the cost of manufacturing each of the LSI chips and the size of the entire LSI chip system. That is to say, the embodiments of the present invention are capable of contributing to the good characteristics of the entire LSI chip system.

In addition, in an LSI chip system including a number of LSI chips, it is possible to get rid of effects of a signal coming from a source external to a chip to be put in a turned-off state and to prevent a penetration current from flowing from the external source to the chip. Thus, it is possible to turn off not only the internal power supply of a chip to be put in a turned-off state, but also a power supply on the interface side. As a result, the embodiments of the present invention are capable of contributing to the lower power consumption of the entire LSI chip system.

On top of that, in an LSI chip system including a number of LSI chips, the LSI chip system does not have to control every LSI chip. For example, an LSI chip is capable of putting the power supply of its own in a turned-off state. Thus, the LSI chip system can be made simple. As a result, it is possible to reduce the cost of manufacturing each of the LSI chips and the size of the entire LSI chip system. That is to say, the embodiments of the present invention are capable of contributing to the good characteristics of the entire LSI chip system.

The present application contains subject matter related to that disclosed in Japanese Priority Patent Application JP 2008-131250 filed in the Japan Patent Office on May 19, 2008, the entire content of which is hereby incorporated by reference.

It should be understood by those skilled in the art that various modifications, combinations, sub-combinations and alterations may occur depending on design requirements and other factor in so far as they are within the scope of the appended claims or the equivalents thereof.

What is claimed is:

1. An output buffer circuit comprising:
a power supply;
an output circuit having
a first field-effect transistor, and
a second field-effect transistor,
said first field-effect transistor and said second field-effect transistor are connected in series between reference electric potentials by linking the drain electrode of said first field-effect transistor to the drain electrode of said second field-effect transistor through a connection point serving as an output node;
an output control circuit for controlling an operation to put the output of said output circuit in the state of a first level, the state of a second level or a high-impedance state;
a substrate-voltage control circuit for connecting the substrate of said first field-effect transistor employed in said output circuit to said power supply of said output circuit when said power supply is put in a turned-on state;
a gate-voltage control circuit for supplying a signal received from another integrated circuit connected to said output node of said output circuit to the gate electrode of said first field-effect transistor employed in said output circuit when said power supply of said output buffer circuit has been put in a turned-off state and said signal received from said other integrated circuit has been in said state of said first level; and
a signal supplying section configured to supply a signal received from another integrated circuit connected to said output node of said output circuit to the substrate of said first field-effect transistor employed in said output circuit when said power supply of said output buffer circuit has been put in a turned-off state and said signal received from said other integrated circuit has been put in said state of said first level.

2. The output buffer circuit according to claim 1 wherein said signal supplying section is implemented as a positive-negative diode created between the drain area and substrate of said first field-effect transistor employed in said output circuit to serve as a diode for supplying a signal received from said other integrated circuit as a signal set in said state of said first level to said substrate.

3. The output buffer circuit according to claim 1 wherein, when said power supply of said output buffer circuit has been put in a turned-off state, said signal supplying section selectively connects said substrate of said first field-effect transistor employed in said output circuit to said output node of said output circuit in order to supply a signal received from said other integrated circuit connected to said output node as a signal set in said state of said first level to said substrate of said first field-effect transistor.

4. The output buffer circuit according to claim 2 wherein:
said substrate-voltage control circuit employs
a first switch connected between said power supply and said substrate of said first field-effect transistor employed in said output circuit, and
a first control section configured to control an operation to put said first switch in a turned-on state when said power supply is put in a turned-on state and an operation to put said first switch in a turned-off state when said power supply is put in a turned-off state; and
said gate-voltage control circuit employs
a second switch connected between a first gate control line for controlling an electric potential appearing on the gate electrode of said first field-effect transistor employed in said output circuit and a second gate control line wired to said gate electrode of said first field-effect transistor,
a third switch connected between said output node of said output circuit and said second gate control line wired to said gate electrode of said first field-effect transistor employed in said output circuit, and
a second control section configured to control an operation to put said second switch in a turned-on state and put said third switch in a turned-off state when said power supply is put in a turned-on state and an operation to put said second switch in a turned-off state and put said third switch in a turned-on state when said power supply is put in a turned-off state.

5. The output buffer circuit according to claim 4 wherein:
said first switch employed in said substrate-voltage control circuit is created as a third field-effect transistor which is put in a turned-off state by a signal set at said first level and put in a turned-on state by said signal set at said second level;
when said power supply is put in a turned-on state, said first control section employed in said substrate-voltage control circuit sustains an electric potential appearing on the gate electrode of said third field-effect transistor at said second level but, when said power supply is put in a turned-off state, on the other hand, said first control section connects said gate electrode of said third field-effect transistor to a connection node wired to said output node of said output circuit to serve as a connection node for connecting said output buffer circuit to another integrated circuit so as to sustain said electric potential appearing on said gate electrode of said third field-effect transistor at an electric potential appearing on said connection node;
said second switch employed in said gate-voltage control circuit is created as a fourth field-effect transistor which is put in a turned-off state by a signal set at said first level and put in a turned-on state by said signal set at said second level;
said third switch employed in said gate-voltage control circuit is created as a fifth field-effect transistor which is put in a turned-off state by a signal set at said first level and put in a turned-on state by said signal set at said second level; and
when said power supply is put in a turned-on state, said second control section employed in said gate-voltage control circuit sustains an electric potential appearing on the gate electrode of said fourth field-effect transistor at said second level but, when said power supply is put in a turned-off state, on the other hand, said second control section connects said gate electrode of said fourth field-effect transistor to said connection node wired to said output node of said output circuit to serve as a connection node for connecting said output circuit to another integrated circuit so as to sustain said electric potential appearing on said gate electrode of said fourth field-effect transistor at an electric potential appearing on said connection node.

6. The output buffer circuit according to claim 5 wherein, when said power supply is put in a turned-off state, said second control section employed in said gate-voltage control circuit sustains an electric potential appearing on the gate electrode of said second field-effect transistor employed in said output circuit at an electric potential that puts said second field-effect transistor in a turned-off state.

7. The output buffer circuit according to claim 3 wherein:
said substrate-voltage control circuit employs
a first switch connected between said power supply and said substrate of said first field-effect transistor employed in said output circuit, and
a first control section configured to control an operation to put said first switch in a turned-on state when said power supply is put in a turned-on state and an operation to put said first switch in a turned-off state when said power supply is put in a turned-off state;
said gate-voltage control circuit employs
a second switch connected between said a first gate control line for controlling an electric potential appearing on said gate electrode of said first field-effect transistor employed in said output circuit and a second gate control line wired to said gate electrode of said first field-effect transistor,
a third switch connected between said output node of said output circuit and said second gate control line wired to said gate electrode of said first field-effect transistor employed in said output circuit, and
a second control section configured to control an operation to put said second switch in a turned-on state and put said third switch in a turned-off state when said power supply is put in a turned-on state and an operation to put said second switch in a turned-off state and put said third switch in a turned-on state when said power supply is put in a turned-off state;
said signal supplying section includes
a fourth switch provided between a connection node wired to said output node of said output circuit to serve as a connection node for connecting said output circuit to another integrated circuit and said substrate of said first field-effect transistor; and
said first control section controls an operation to put said fourth switch in a turned-on state when said power supply is put in a turned-off state.

8. The output buffer circuit according to claim 7 wherein:
said first switch employed in said substrate-voltage control circuit is created as a third field-effect transistor which is put in a turned-off state by a signal set at said first level and put in a turned-on state by said signal set at said second level;
when said power supply is put in a turned-on state, said first control section employed in said substrate-voltage control circuit sustains an electric potential appearing on the gate electrode of said third field-effect transistor at said second level but, when said power supply is put in a turned-off state, on the other hand, said first control section connects said gate electrode of said third field-effect transistor to a connection node wired to said output node of said output circuit to serve as a connection node for connecting said output circuit to another integrated circuit so as to sustain said electric potential appearing on said gate electrode of said third field-effect transistor at an electric potential appearing on said connection node;
said second switch employed in said gate-voltage control circuit is created as a fourth field-effect transistor which is put in a turned-off state by a signal set at said first level and put in a turned-on state by said signal set at said second level;
said third switch employed in said gate-voltage control circuit is created as a fifth field-effect transistor which is put in a turned-off state by a signal set at said first level and put in a turned-on state by said signal set at said second level;
when said power supply is put in a turned-on state, said second control section employed in said gate-voltage control circuit sustains an electric potential appearing on the gate electrode of said fourth field-effect transistor at said second level but, when said power supply is put in a turned-off state, on the other hand, said second control section connects said gate electrode of said fourth field-effect transistor to said connection node wired to said output node of said output circuit to serve as a connection node for connecting said output buffer circuit to another integrated circuit so as to sustain said electric potential appearing on said gate electrode of said fourth field-effect transistor at an electric potential appearing on said connection node;
said fourth switch employed in said signal supplying section is created as a sixth field-effect transistor which is put in a turned-off state by a signal set at said first level and put in a turned-on state by said signal set at said second level; and
the gate electrode of said sixth field-effect transistor is connected to said power supply to serve as a sub-power supply for generating a voltage corresponding to said first level for putting said sixth field-effect transistor in a turned-off state when said power supply is put in a turned-on state and generating a voltage corresponding to said second level for putting said sixth field-effect transistor in a turned-on state when said power supply is put in a turned-off state.

9. The output buffer circuit according to claim 8 wherein, when said power supply is put in a turned-off state, said second control section employed in said gate-voltage control circuit sustains an electric potential appearing on the gate electrode of said second field-effect transistor employed in said output circuit at an electric potential that puts said second field-effect transistor in a turned-off state.

10. An integrated circuit including
an output section with a connection node connected to another integrated circuit, including
an output buffer circuit employing
a power supply,
an output circuit having
a first field-effect transistor, and
a second field-effect transistor,
said first-effect transistor and said second-effect transistor are connected in series between reference electric potentials by linking the drain electrode of said first field-effect transistor to the drain electrode of said second field-effect transistor through a connection point serving as an output node,
an output control circuit for controlling an operation to put the output of said output circuit in the state of a first level, the state of a second level or a high-impedance state,
a substrate-voltage control circuit for connecting the substrate of said first field-effect transistor employed in said output circuit to said power supply of said output circuit when said power supply is put in a turned-on state,
a gate-voltage control circuit for supplying a signal received from another integrated circuit connected to said output node of said output circuit to the gate electrode of said first field-effect transistor employed in said output circuit when said power supply of said output circuit has been put in a turned-off state and said signal received from said other integrated circuit has been in said state of said first level, and
a signal supplying section configured to supply a signal received from another integrated circuit connected to said output node of said output circuit to the substrate of said first field-effect transistor employed in said output circuit when said power supply of said output buffer circuit has been put in a turned-off state and said signal received from said other integrated circuit has been put in said state of said first level.

11. The integrated circuit according to claim 10 wherein said signal supplying section is implemented as a positive-negative diode created between the drain area and substrate of said first field-effect transistor employed in said output circuit to serve as a diode for supplying a signal received from said other integrated circuit as a signal set in said state of said first level.

12. The integrated circuit according to claim 10 wherein, when said power supply of said output circuit has been put in a turned-off state, said signal supplying section selectively connects said substrate of said first field-effect transistor employed in said output circuit to said output node of said output circuit in order to supply a signal received from said other integrated circuit connected to said output node as a signal set in said state of said first level to said substrate of said first field-effect transistor.
